(19) United States
(12) Patent Application Publication
(10) Pub. No.: US 2024/0429217 A1
(43) Pub. Date: Dec. 26, 2024

(54) POWER MODULE WITH INDUCTORS AND CAPACITORS THAT ARE EMBEDDED WITHIN A SUBSTRATE LAYER

(71) Applicant: Monolithic Power Systems, Inc., San Jose, CA (US)

(72) Inventors: Daocheng HUANG, San Jose, CA (US); Xinmin ZHANG, San Jose, CA (US); Yishi SU, San Jose, CA (US); Yingxin ZHOU, San Jose, CA (US); Wenyang HUANG, San Jose, CA (US); Ting GE, San Jose, CA (US)

(21) Appl. No.: 18/830,167

(22) Filed: Sep. 10, 2024

Related U.S. Application Data
(63) Continuation-in-part of application No. 17/870,555, filed on Jul. 21, 2022, now Pat. No. 12,120,822.
Application No. 17/870,555 is a continuation-in-part of application No. 17/678,172, filed on Feb. 23, 2022, now Pat. No. 12,095,369.

(51) Int. Cl. H01L 25/16; H01L 23/373; H01L 23/538; H01L 29/78; H05K 1/18

(52) U.S. Cl. CPC H01L 25/16; H01L 23/3736; H01L 23/5386; H01L 28/10; H01L 28/40; H05K 1/181; H05K 1/185; H01L 29/78

(57) ABSTRACT

A power module includes a substrate and an integrated circuit (IC) die. The IC die is disposed on the substrate. A driver and a pair of switches are integrated in the IC die. A power converter of the power module includes the driver, the pair of switches, an inductor, and a capacitor. The inductor and the capacitor are embedded within the substrate.

### CROSS-REFERENCE TO RELATED APPLICATIONS

The present application is a continuation-in-part of U.S. application Ser. No. 17/870,555, filed on Jul. 21, 2022, which is a continuation-in-part of U.S. application Ser. No. 17/678,172, filed on Feb. 23, 2022. Both of these related applications are incorporated herein by reference in their entirety.

### TECHNICAL FIELD

The present invention is directed to electrical circuits, and more particularly but not exclusively to power modules.

### BACKGROUND

A power module comprises power converters that are implemented on a substrate, such as a printed circuit board (PCB). Power modules may be employed to provide one or more supply voltages to various electrical devices. A power module may provide two or more output phases by incorporating a corresponding number of power converters, with each power converter providing a phase of the output. Embodiments of the present invention pertain to power modules with a low profile, allowing them to be used in automotive, computer server, and other applications where space is a premium.

### BRIEF SUMMARY

In one embodiment, a power module comprises a printed circuit board (PCB), a first integrated circuit (IC) die, a second IC die, a first output inductor, a second output inductor, and an output capacitor. The first IC is disposed on the PCB, wherein a first gate driver and a first pair of switches are integrated in the first IC die. The second IC die is disposed on the PCB, wherein a second gate driver and a second pair of switches are integrated in the second IC die. The first output inductor is embedded within a substrate layer of the PCB, the first output inductor comprises a first end that is connected to an output voltage node of the power module and a second end that is connected to a switch node of the first pair of switches. The second output inductor is embedded within the substrate layer, the second output inductor comprises a first end that is connected to the output voltage node and a second end that is connected to a switch node of the second pair of switches. The output capacitor is embedded within the substrate layer, the output capacitor comprising a first end that is connected to the output voltage node and a second end that is connected to a power ground.

In another embodiment, a power module comprises an IC die, an output inductor, and an output capacitor. A gate driver and a pair of switches are integrated in the IC die. The output inductor is embedded within a substrate layer, the first output inductor having a first end that is connected to an output voltage node of the power module and a second end that is connected to a switch node formed by the pair of switches. The output capacitor is embedded within the substrate layer, the output capacitor having a first end that is connected to the output voltage node and a second end that is connected to a power ground.

In yet another embodiment, a power module comprises a substrate, a power stage layer, an inductor, a capacitor, an IC die, and a copper block. The power stage layer is disposed on the substrate. The inductor and the capacitor are embedded within a layer of the substrate. The IC die is disposed in the power stage layer, wherein a driver and a pair of switches are integrated in the IC die. The copper block is disposed on the IC die. The power module comprises a power converter, and the power converter comprises the inductor, the capacitor, the driver, and the pair of switches.

These and other features of the present disclosure will be readily apparent to persons of ordinary skill in the art upon reading the entirety of this disclosure, which includes the accompanying drawings and claims.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures. The figures are not drawn to scale.

FIG. 1 shows a schematic diagram of a power module in accordance with an embodiment of the present invention.

FIG. 2 shows a top view, a bottom view, and a side view of a physical layout of the power module of FIG. 1 in accordance with an embodiment of the present invention.

FIG. 3 shows a cross-sectional view of a substrate of the power module of FIG. 2 in accordance with an embodiment of the present invention.

FIG. 4 shows a top view of a physical layout of a power module in accordance with an embodiment of the present invention.

FIG. 5 shows a side view of the power module of FIG. 4 in accordance with an embodiment of the present invention.

FIG. 6 shows a cross-sectional view of the power module of FIG. 4 in accordance with an embodiment of the present invention.

FIG. 7 shows a top surface of an output capacitor substrate layer in accordance with an embodiment of the present invention.

FIG. 8 shows a side view of a power module in accordance with an embodiment of the present invention.

FIG. 9 shows a side cross-sectional view of the power module of FIG. 8 in accordance with an embodiment of the present invention

### DETAILED DESCRIPTION

In the present disclosure, numerous specific details are provided, such as examples of circuits, components, and methods, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

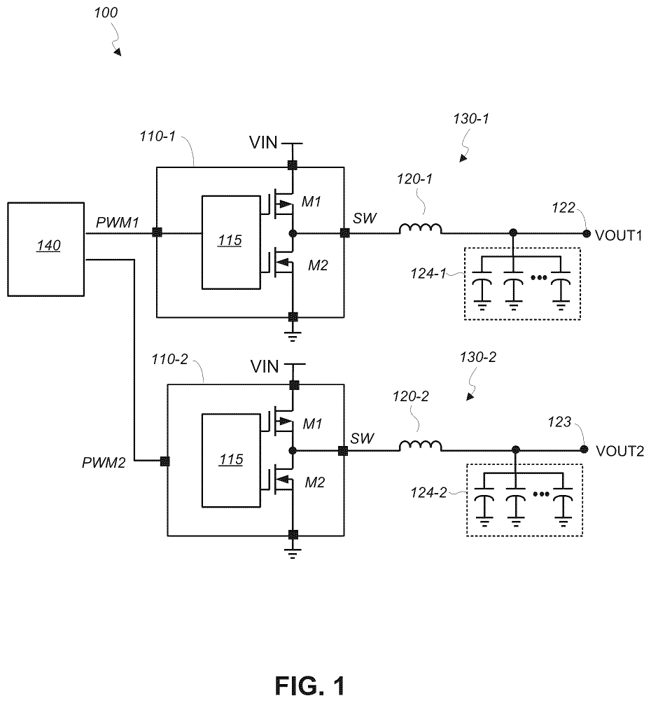

FIG. 1 shows a schematic diagram of a power module 100 in accordance with an embodiment of the present invention. In the example of FIG. 1, the power module 100 has two power converters 130 (i.e., 130-1, 130-2), with each power converter 130 comprising an output inductor 120 (i.e., 120-1, 120-2), an output capacitor 124 (i.e., 124-1, 124-2), and a monolithic integrated circuit (IC) switch block 110 (i.e., 110-1, 110-2). In one embodiment, an output capacitor 124 comprises a plurality of discrete capacitors that are connected in parallel. In the example of FIG. 1, a power converter 130 is a buck converter. As can be appreciated, a power converter 130 may also be configured as a boost converter or other type of power converter depending on the application.

Each of the power converters 130-1 and 130-2 receives an input voltage VIN to generate an output voltage VOUT (i.e., VOUT1, VOUT2). The output voltages of the power converters 130-1 and 130-2 may be connected together and interleaved to generate a multiphase output voltage. For example, an output voltage node 122 and an output voltage node 123 may be connected together, with each power converter 130 providing a phase of a multiphase output voltage. In that example, the power module 100 may include additional power converters to add more phases.

An output capacitor 124 is connected to each output voltage node. In the example of FIG. 1, an output capacitor 124-1 has a first end that is connected to the output voltage node 122 and a second end that is connected to power ground. Similarly, an output capacitor 124-2 has a first end that is connected to the output voltage node 123 and a second end that is connected to power ground. Other capacitors (e.g., input capacitors, supply capacitors) and other components not necessary to the understanding of the invention are not shown in FIG. 1 for clarity of illustration.

In one embodiment, a switch block 110 is implemented using an MP86976 Intelli-Phase™ Solution monolithic IC, which is commercially-available from Monolithic Power Systems, Inc. Other suitable monolithic IC's may also be used without detracting from the merits of the present invention. A switch block 110 has, integrated therein, a driver 115 and a pair of switches M1, M2 (e.g., Metal-Oxide-Semiconductor Field-Effect Transistor (MOSFET)). Other circuits for implementing the driver 115, such as an auxiliary 3.3V power supply circuit, are not shown for clarity of illustration. As shown in FIG. 1, a switch block 110 has a first pin for receiving a pulse width modulation (PWM) signal, a second pin for receiving an input voltage VIN, a third pin for connecting to power ground, and a fourth pin that is connected to a switch node SW formed by the switches M1, M2. The drain of the switch M1 is connected to the input voltage VIN and the source of the switch M2 is connected to power ground. The source of the switch M1 is connected to the drain of the switch M2 at the switch node SW.

Generally speaking, PWM control is well-known in the art. Briefly, an external PWM controller 140 generates a PWM signal, which is received by a driver 115 at the first pin of the switch block 110. The driver 115 turns the switches M1, M2 ON and OFF in accordance with the PWM signal. Turning the switch M1 ON while turning the switch M2 OFF connects the input voltage VIN to the switch node SW (by way of the switch M1), whereas turning the switch M1 OFF while turning the switch M2 ON connects the switch node SW to power ground (by way of the switch M2). A first end of an output inductor 120 is connected to the switch node SW and a second end of the output inductor 120 is connected to an output voltage node (i.e., 122, 123) where an output voltage VOUT is developed. In the example of FIG. 1, the PWM controller 140 generates the PWM signals PWM1, PWM2 such that a corresponding output voltage VOUT is maintained in regulation. Other circuits for implementing the PWM control, such as sense circuits, are not shown for clarity of illustration.

The input voltage VIN, output voltage VOUT, and switching frequency of the switches M1, M2 depend on the particulars of the monolithic IC switch block 110. In one embodiment where the monolithic IC switch block 110 is implemented using the aforementioned MP86976 Intelli-Phase™ Solution monolithic IC, the input voltage VIN is in the range of 3V to 7V, the output voltage VOUT is in the range of 0.4V to 2V (e.g., 0.8V), and the switching frequency of the switches M1, M2 is in the range of 1 MHz to 2 MHZ (e.g., 1.5 MHZ). The relatively low input voltage VIN and relatively high switching frequency of the switches M1, M2 allow for a relatively small physical size of the output inductor 120 (e.g., 2.5 mm×5 mm×1.2 mm). As will be more apparent below, the output inductor 120 may be embedded within the substrate of the power module 100 to achieve a low profile.

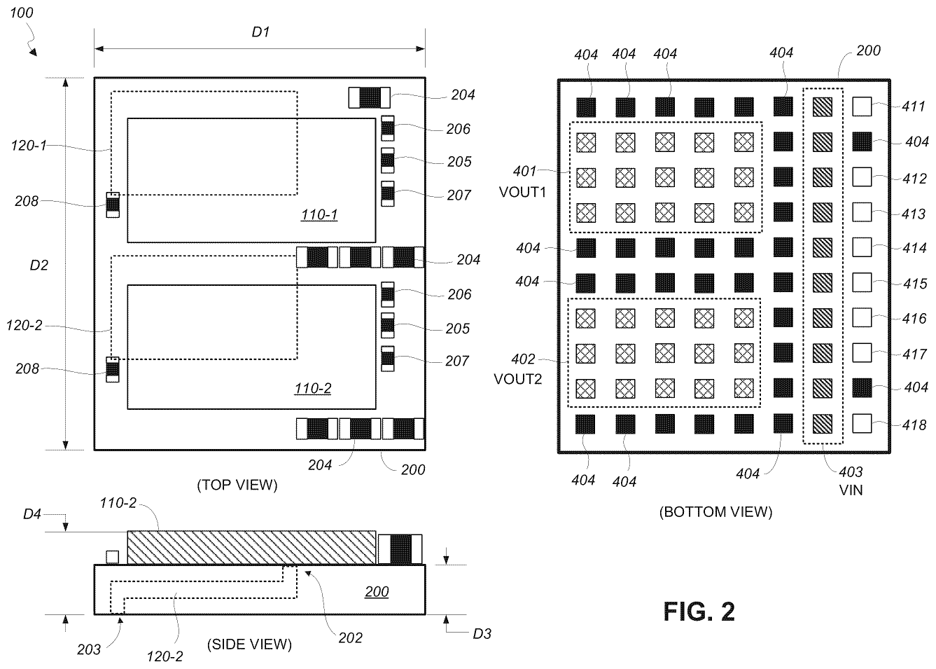

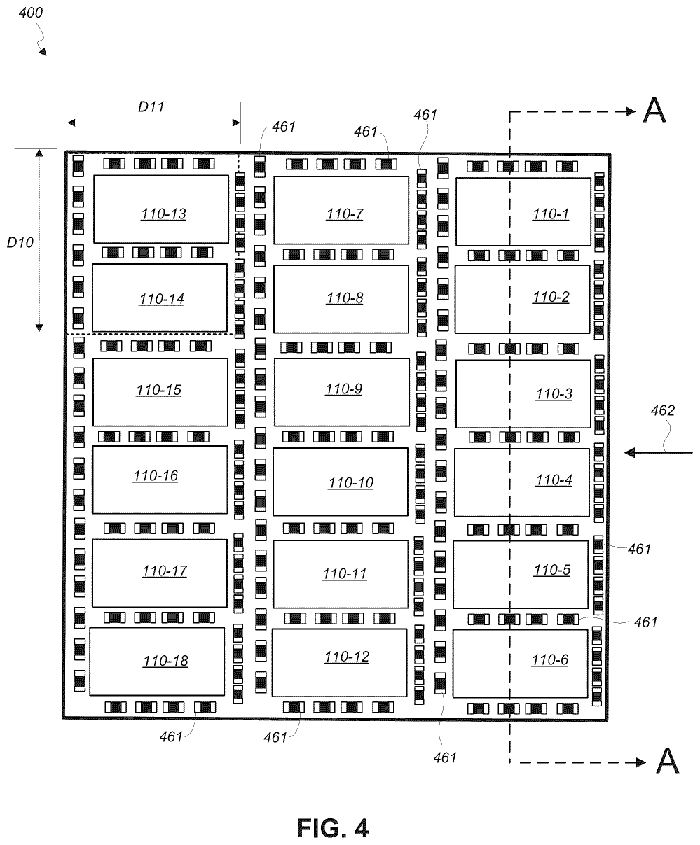

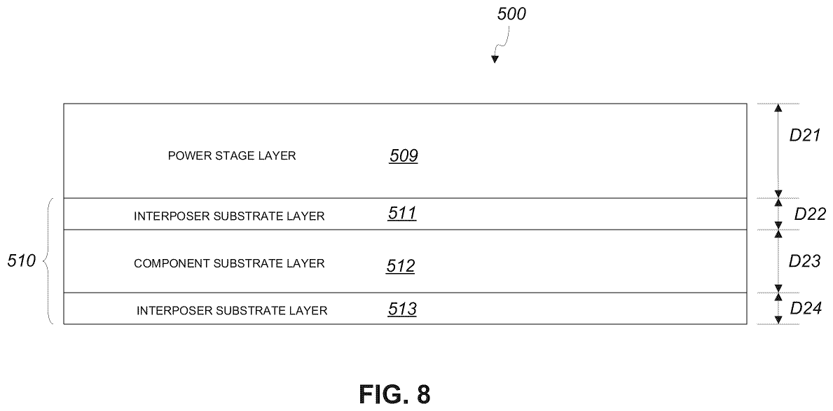

FIG. 2 shows, from the upper left hand corner in clock-wise direction, a top view, a bottom view, and a side view of a physical layout of the power module 100 in accordance with an embodiment of the present invention. The power module 100 has a substrate 200, which in one embodiment is a printed circuit board (PCB). The top view of the substrate 200 shows the “component side” of the substrate 200, whereas the bottom view shows the bottom side of the substrate 200. In the example of FIG. 2, the switch blocks 110, capacitors, and other components are mounted on the component side. In other embodiments, as will be later explained beginning with FIG. 4, output capacitors are disposed within a separate output capacitor substrate layer. In yet other embodiments, as will be later explained beginning with FIG. 8, output capacitors and output inductors are disposed within the same substrate layer.

In the example of FIG. 2, the bottom side, which is opposite the component side, has a plurality of pins that connect nodes of the power module 100 to components that are external to the power module 100, such as a PWM controller, etc. A pin may be a pad or other means for electrically connecting nodes and components. A pin may have a square (e.g., as in a land grid array), round (e.g., as in a ball grid array), or other shape. The power module 100 may be employed as part of a power supply (not shown). The pins of the power module 100 may be connected to corresponding sockets on a substrate of the power supply.

The top view of the power module 100 shows the switch block 110-1, switch block 110-2, and various capacitors mounted on the component side, such as input capacitors (e.g., see 204), capacitors of RC filters of supply voltages for internal digital logic control (e.g., 205, 207), bootstrap capacitors (e.g., see 206), filter capacitors of supply voltages for switch drivers (e.g., see 208), etc. As can be appreciated, the number and type of capacitors on the power module 100 depend on the particulars of the application. Generally, the capacitors on the power module 100 have relatively low capacitance. In the example of FIG. 2, a switch block 110 is the tallest component on the substrate 200. In one embodiment, the substrate 200 has a width D1 of about 8 mm; a length D2 of about 9 mm, and a substrate thickness D3 of about 1.5 mm. In one embodiment, a height D4 from the bottom surface of the substrate 200 to the topmost surface of a switch block 110 is 2.3 mm.

The output inductors 120-1 and 120-2, which are represented by dotted lines in FIG. 2, are embedded within the substrate 200. A first end of an output inductor 120 (see 202) is connected to a switch node of a corresponding switch block 110, and a second end of the output inductor 120 (see 203) is connected to a corresponding output voltage node. The relatively low inductance of each of the output inductors 120-1 and 120-2 in conjunction with the layout of the power module 100 allow the output inductors 120-1 and 120-2 to be embedded within the substrate 200, thereby lowering the profile of the power module 100. In one embodiment, the height D4 of the power module 100 is 2.3 mm and at most 5 mm.

In the example of FIG. 2, each pin of the power module 100 has a square shape, e.g., 0.45 mm×0.45 mm square. The pins that are connected to power ground, some of which are labeled as “404”, are depicted in black. Not all of the ground pins are labeled for clarity of illustration. The pins that are connected to the output voltage node 122 (shown in FIG. 1), where the output voltage VOUT1 is developed, are collectively labeled as “401”; the pins that are connected to the output voltage node 123 (shown in FIG. 1), where the output voltage VOUT2 is developed, are collectively labeled as “402”; and the pins that are connected to receive the input voltage VIN are collectively labeled as “403”. Pin 411 is connected to receive a PWM signal to the switch block 110-1; pin 418 is connected to receive a PWM signal to the switch block 110-2; pin 412 is connected to provide a current monitor signal from the switch block 110-1; pin 417 is connected to provide a current monitor signal from the switch block 110-2; pin 413 is connected to provide a temperature monitoring signal from the switch block 110-1; pin 416 is connected to provide a temperature monitoring signal from the switch block 110-2; pin 414 is connected to receive a VCC supply voltage; and pin 415 is connected to receive an enable signal. As can be appreciated, the pinout of the power module 100 depends on implementation details, such as the particular switch block 110 employed. The arrangement of the pins on the bottom surface of the substrate 200 may vary to suit particular applications.

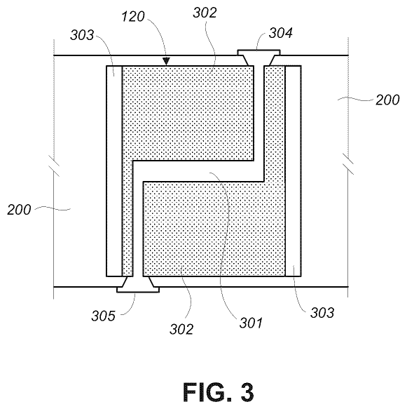

FIG. 3 shows a cross-sectional view of the substrate 200 in accordance with an embodiment of the present invention. FIG. 3 provides a schematic illustration of an output inductor 120 and is not to scale. In one embodiment, the output inductor 120 is a one turn inductor. The output inductor 120 may also have a few number of turns. The output inductor 120 comprises a conductor 301 and a magnetic core 302 that surrounds the conductor 301. In one embodiment, the conductor 301 comprises copper and the magnetic core 302 comprises a suitable core material, such as ferrite or powder iron. A gap 303 is between the magnetic core 302 and the substrate material, which in one embodiment comprises a PCB substrate. Generally speaking, a PCB is a laminated sandwich structure of conductive layers (e.g., copper) and insulating/dielectric layers (e.g., fiberglass epoxy laminate). The gap 303 may be an air gap that is filled with epoxy molding compound. A first end of the conductor 301 (see 304) comes out of the component side of the substrate 200 to connect to the switch node of a corresponding switch block 110, and a second end of the conductor 301 (see 305) comes out of the bottom side of the substrate 200 to a pin that is connected to a corresponding output voltage node.

In one embodiment, the output inductor 120 has an inductance less than 100 nH. As can be appreciated, the inductance of the output inductor 120 may vary depending on the volume of the substrate 200. Larger substrates allow physically larger inductors to be embedded. For example, with a thickness D3 (shown in FIG. 2) of 1.5 mm, the output inductor 120 may have dimensions of 2.5 mm×5 mm×1.2 mm with an inductance of about 30 nH.

FIG. 4 shows a top view of a physical layout of the power module 400 in accordance with an embodiment of the present invention. The top view of FIG. 4 shows a topmost surface of the PCB of the power module 400 where switch blocks 110 (i.e., 110-1, 110-2, . . . , 110-18), capacitors 461 (e.g., input capacitors, bootstrap capacitors, filter capacitors, supply capacitors, etc.), and other components (not shown) of the power module 400 are mounted. Each of the switch blocks 110 of the power module 400 may be employed in a power converter 130 as described in connection with FIG. 1. Generally speaking, the number of power converters on a power module, and thus the number of switch blocks, depends on the particulars of the application.

In the example of FIG. 4, the switch blocks 110 are physically arranged in groups of two (e.g., switch blocks 110-1 and 110-2 as one group; switch blocks 110-13 and 110-14 as another group; etc.), with each group of switch blocks having a length D10 of 8 mm and a width D11 of 8 mm. The switch blocks 110 may be configured to generate one or more output voltages. For example, the output voltage node of the switch block 110-1 may provide a first output voltage, and the output voltage node of the switch block 110-2 may provide a second output voltage, with each of the first and second output voltages being independent, separate output voltages. As another example, the output voltage nodes of the switch blocks 110-1 to 110-12 may be tied together to provide a first multiphase output voltage, and the output voltage nodes of the switch blocks 110-13 to 110-18 may be tied together to provide a second multiphase output voltage. All of the output voltages of the switch blocks 110 may also be tied together to generate a single multi-phase output voltage.

The power module 400 has 18 switch blocks 110 for illustration purposes only. As can be appreciated, fewer or more switch blocks 110 may be employed depending on the number of power converters provided by the power module 400. The specific layout of the components of the power module 400 may be configured to suit application details.

The power module 400 may be employed in various applications including graphics processing unit (GPU), central processing unit (CPU), application-specific integrated circuit (ASIC), etc. applications. During fast load transients, a sufficient number of output capacitors is required to limit output voltage undershoot and overshoot. However, output capacitors consume a lot of board space and decrease circuit density. This problem is especially troublesome in applications with a fixed board form factor, where the board space required by the output capacitors reduces the number of power converters available on the power module, thereby limiting the power that can be delivered to GPUs, CPUs, etc. In embodiments of the present invention, to conserve board space, an output capacitor of a power converter 130 is implemented by a plurality of parallel-connected discrete capacitors embedded within an output capacitor substrate layer of the PCB instead of on a topmost surface of the PCB.

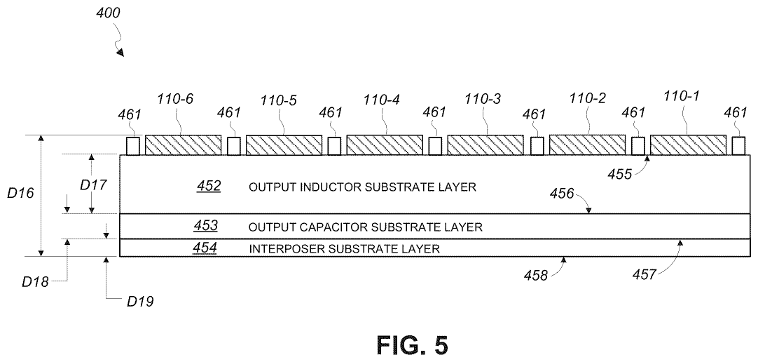

FIG. 5 shows a side view of the power module 400, as viewed in the direction of arrow 462 of FIG. 4. The power module 400 is implemented using a PCB comprising a plurality of substrate layers, namely an output inductor substrate layer 452, an output capacitor substrate layer 453, and an interposer substrate layer 454. Advantageously, the output inductor substrate layer 452 is between the switch blocks 110 and the output capacitor substrate layer 453 to allow a terminal of an output inductor to be efficiently connected to a switch node of a switch block 110.

In the example of FIG. 5, a top surface 455 of the output inductor substrate layer 452 serves as a topmost surface of the PCB on which the switch blocks 110, capacitors 461, and other components of the power module 400 are mounted. A bottom surface 458 of the interposer substrate layer 454 serves as the bottommost surface of the PCB on which pins of the power module 400 are exposed for external connection (e.g., as in the bottom view of FIG. 2). For example, the output voltage nodes 122 and 123 (shown in FIG. 1) may be connected to corresponding pins on the bottom surface 458 of the interposer substrate layer 454. A pin may have a square (e.g., as in a land grid array), round (e.g., as in a ball grid array), or other shape. As can be appreciated, the pinout of the power module 400 depends on implementation details, such as the particular switch blocks 110 employed. The arrangement of the pins on the bottom surface 458 may vary to suit particular applications.

In the example of FIG. 5, the output inductor substrate layer 452 has a bottom surface 456 that directly contacts a top surface of the output capacitor substrate layer 453. The interposer substrate layer 454 has a top surface 457 that directly contacts a bottom surface of the output capacitor substrate layer 453. In one embodiment, the output inductor substrate layer 452 has a thickness D17 of 2.32 mm, the output capacitor substrate layer 453 has a thickness D18 of 0.5 mm, and the interposer substrate layer 454 has a thickness D19 of 0.4 mm. The power module 400 has an overall height D16 of 4 mm measured from the bottom surface 458 of the interposer substrate layer 454 to a topmost surface of a tallest component mounted on the power module 400, which in one embodiment is a switch block 110. The power module 400 may have an overall height of at most 8 mm.

The output inductor substrate layer 452 provides a layer where the output inductors 120 (shown in FIG. 1) may be embedded within. The output inductors 120 may be embedded within the output inductor substrate layer 452 as explained with reference to FIGS. 2 and 3 except that an end of an output inductor 120 that extends out of the bottom surface now extends to the top surface of the output capacitor substrate layer 453. Electrical connections between and through the substrate layers 452-454 may be made by way of vias and/or nodes in the substrate layers 452-454.

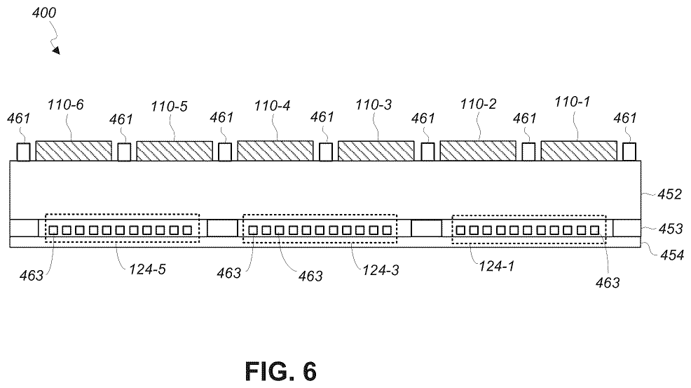

FIG. 6 shows a cross-sectional view of the power module 400 in accordance with an embodiment of the present invention. FIG. 6 is taken at cross-section A-A of FIG. 4. In one embodiment, an output capacitor 124 is implemented by a plurality of discrete (i.e., single, individual component; not part of an integrated circuit), embedded capacitors 463 that are connected in parallel and embedded within the output capacitor substrate layer 453. Note that not all of the embedded capacitors 463 are labeled in FIG. 6 for clarity of illustration. In one embodiment, an embedded capacitor 463 is a size 0201 capacitor. Other discrete capacitor sizes, such as size 0402, may also be used depending on available space in the output capacitor substrate layer 453 and the particular capacitance value of the output capacitor 124. The embedded capacitors 463 may be placed in one or more cavities or other carved out regions within the output capacitor substrate layer 453. In one embodiment, the embedded capacitors 463 are the only discrete components embedded within the output capacitor substrate layer 453. FIG. 6 shows the embedded capacitors 463 of the output capacitors 124-1, 124-3, and 124-5 in cavities embedded within the output capacitor substrate layer 453.

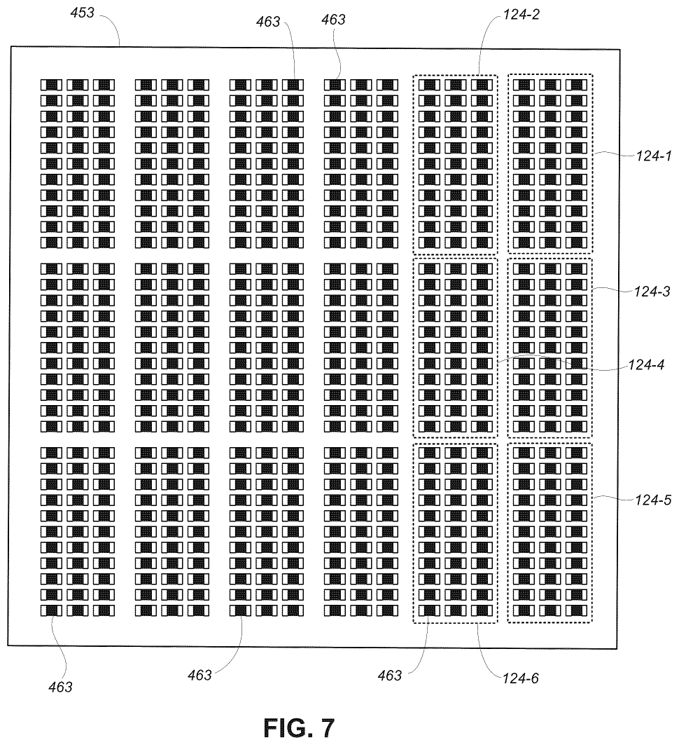

FIG. 7 shows the top view of the output capacitor substrate layer 453 in accordance with an embodiment of the present invention. In the example of FIG. 7, the embedded capacitors 463 are physically arranged in blocks of 33 discrete capacitors, with each block forming an output capacitor 124. The blocks of embedded capacitors 463 are arranged as a 6×3 array. FIG. 7 shows the embedded capacitors 463 that form the output capacitors 124-1, 124-2, 124-3, etc. Only some of the embedded capacitors 463 forming the output capacitors 124 are labeled for clarity of illustration.

In light of the present disclosure, one of ordinary skill in the art will appreciate that capacitors and inductors of power modules may also be embedded within the same substrate layer. For example, one or more output capacitors and inductors of power converters of a power module may be embedded within the same substrate layer of a multilayer PCB.

FIG. 8 shows a side view of a power module 500 in accordance with an embodiment of the present invention. The power module 500 comprises a power stage layer 509 and a substrate 510. In one embodiment, the substrate 510 is a multilayer PCB comprising an interposer substrate layer 511, a component substrate layer 512, and an interposer substrate layer 513. FIG. 8 is not drawn to scale. In one embodiment, the power stage layer has a thickness D21 of 0.8 mm, the substrate layer 511 has a thickness D22 of 0.33 mm, the substrate layer 512 has a thickness D23 of 1.5 mm, and the substrate layer 513 has a thickness D24 of 0.33 mm. The substrate 510 may have fewer or additional layers with different thicknesses depending on the application. The power stage layer 509 is disposed on the topmost layer of the substrate 510, which in the example of FIG. 8 is the interposer substrate layer 511.

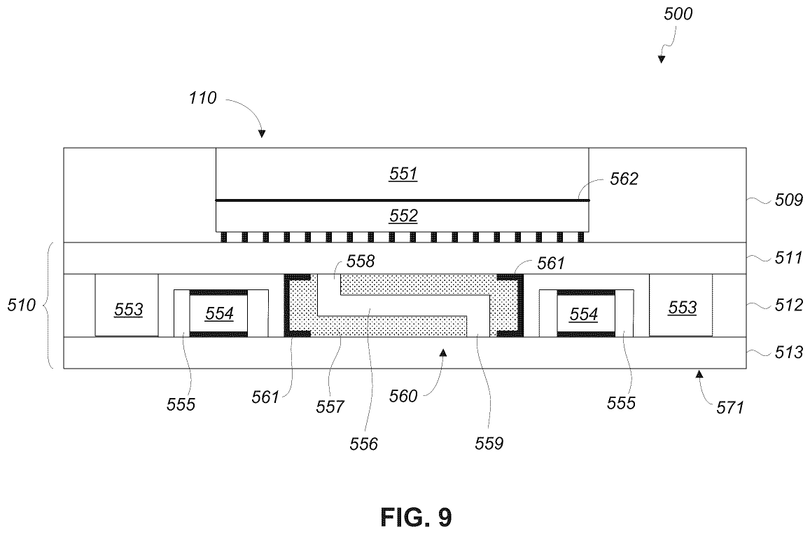

FIG. 9 shows a side cross-sectional view of the power module 500 in accordance with an embodiment of the present invention. In one embodiment, a switch block 110 is embedded within the power stage layer 509. In the example of FIG. 9, the switch block 110 is a DrMOS (Driver-MOSFET) comprising an IC die (e.g., silicon die) 552 and a copper block 551. The copper block 551 is disposed on a top surface of the IC die 552. The copper block 551 may be attached to the IC die 552 by a thermal interface material (TIM) 562, such as a thermal adhesive. The IC die 552 and copper block 551 may be encapsulated by molding compound, or other IC packaging material, within the power stage layer 509. In the example of FIG. 9, the copper block 551 is exposed to the environment on the topmost surface of the power stage layer 509. The heatsink 551 and the thermal interface material 562 are not needed in some applications, in which case the IC die 552 is mainly surrounded by molding compound.

In one embodiment, the IC die 552 embodies at least one gate driver 115 and a pair of switches M1, M2 (shown in FIG. 1). The power module 500 may have additional phases or output voltages by incorporating additional dies 552 in the power stage layer 509 or incorporating additional driver/switch pairs in each die 552. Disposing the power stage layer 509, and consequently the copper block 551, on the topmost layer of the substrate 510 advantageously improves heat dissipation.

In one embodiment, the substrate layer 511 is an interposer layer that includes vias and other interconnect structures for electrically connecting nodes of circuits incorporated in the die 552 to electronic components embedded within the substrate layer 512. Similarly, the substrate layer 513 is an interposer layer that includes vias and other interconnect structures for electrically connecting electronic components embedded within the substrate layer 512 to pins or pads on the bottom surface 571 of the substrate layer 513 or to other nodes/electronic components below the substrate layer 513. For example, pins on the bottom surface 571 of the substrate layer 513 may interface to other components that are external to the power module 500, such as a PWM controller, etc. Such other components may be on another substrate or substrate layer that is below the substrate layer 513.

Embedded within the substrate layer 512 are electronic components, which in one embodiment are one or more capacitors 554 and one or more inductors 560. In one embodiment, the substrate layer 512 has cavities 555 (or other carved out region) where the capacitors 554 are disposed. A capacitor 554 may be a size 0201 discrete capacitor, for example.

In the example of FIG. 9, the inductor 560 is a single turn inductor that comprises a conductor 556 and a magnetic core 557. In one embodiment, the inductor 560 and the capacitors 554 function as an output inductor 120 and output capacitor 124, respectively, of a power converter 130 (shown in FIG. 1) of the power module 500. A first end of the capacitor 554 is electrically connected to an end 559 of the conductor 556, and a second end of the capacitor 554 is electrically connected to power ground. The end 559 of the conductor 556 is electrically connected to an output voltage node of the power module 500, and an end 558 of the conductor 556 is electrically connected to a switch node SW of a corresponding pair of switches M1, M2 integrated in the die 552. As can be appreciated, electrical connections may be made by way of vias and other interconnect structures in the substrate layers 511 and 513, as appropriate.

In the example of FIG. 9, copper blocks 553 and interconnect structures 561 function as vias to provide an electrical connection through the substrate layer 512. In one embodiment, the interconnect structures 561 are attached to the sidewalls of the magnetic core 557. Other interconnect structures may also be used without detracting from the merits of the present invention.

FIG. 9 depicts a single switch block 110 for clarity of illustration. As can be appreciated, the power module 500 may include a plurality of switch blocks 110. For example, a plurality of IC dies 552 may be embedded within the power stage layer 509, with each IC die 552 having a gate driver 115 and a pair of switches M1, M2 of a power converter 130. A plurality of inductors 560 and capacitors 554 may be embedded within the substrate layer 512 to provide output inductors and output capacitors to the plurality of power converters 130.

Low-profile power modules have been disclosed. While specific embodiments of the present invention have been provided, it is to be understood that these embodiments are for illustration purposes and not limiting. Many additional embodiments will be apparent to persons of ordinary skill in the art reading this disclosure.

What is claimed is:

1. A power module comprising:
a printed circuit board (PCB) comprising a first substrate layer;
a first integrated circuit (IC) die that is disposed on the PCB, wherein a first gate driver and a first pair of switches are integrated in the first IC die;
a second IC die that is disposed on the PCB, wherein a second gate driver and a second pair of switches are integrated in the second IC die;
a first output inductor that is embedded within the first substrate layer, the first output inductor comprising a first end that is connected to an output voltage node of the power module and a second end that is connected to a switch node of the first pair of switches;
a second output inductor that is embedded within the first substrate layer, the second output inductor comprising a first end that is connected to the output voltage node and a second end that is connected to a switch node of the second pair of switches; and
an output capacitor that is embedded within the first substrate layer, the output capacitor comprising a first end that is connected to the output voltage node and a second end that is connected to a power ground.

2. The power module of claim 1, wherein the PCB further comprises a second substrate layer that is disposed between the first and second IC dies and the first substrate layer, wherein the second substrate layer is an interposer layer.

3. The power module of claim 2, further comprising a first copper block that is disposed on a topmost surface of the first IC die and a second copper block that is disposed on a topmost surface of the second IC die.

4. The power module of claim 3, wherein the first IC die and the second IC die are embedded within a power stage layer that is disposed on the PCB.

5. The power module of claim 4, wherein the first copper block and the second copper block are exposed to an environment on a topmost surface of the power stage layer.

6. The power module of claim 1, wherein the first and second output capacitors are disposed in one or more cavities within the first substrate layer.

7. A power module comprising:
a first integrated circuit (IC) die, wherein a first gate driver and a first pair of switches are integrated in the first IC die;
a first output inductor that is embedded within a first substrate layer, the first output inductor having a first end that is connected to an output voltage node of the power module and a second end that is connected to a switch node formed by the first pair of switches; and
an output capacitor that is embedded within the first substrate layer, the output capacitor having a first end that is connected to the output voltage node and a second end that is connected to a power ground.

8. The power module of claim 7, further comprising
a second IC die, wherein a second gate driver and a second pair of switches are integrated in the second IC die; and
a second output inductor that is embedded within the first substrate layer, the second output inductor having a first end that is connected to the output voltage node and a second end that is connected to a switch node formed by the second pair of switches.

9. The power module of claim 7, further comprising:
a copper block that is disposed on a top surface of the first IC die.

10. The power module of claim 9, wherein the first IC die is embedded within a power stage layer.

11. The power module of claim 10, wherein the copper block is exposed to an environment through a top surface of the power stage layer.

12. The power module of claim 10, further comprising:
a second substrate layer that is disposed between the power stage layer and the first substrate layer, the second substrate layer including interconnect structures that electrically connect one or more nodes in the first IC die to electronic components embedded within the first substrate.

13. The power module of claim 12, wherein the first and second substrate layers are layers of a multilayer printed circuit board (PCB).

14. A power module comprising:
a substrate;
a power stage layer that is disposed on the substrate;
an inductor and a capacitor that are embedded within a layer of the substrate;
an integrated circuit (IC) die that is disposed in the power stage layer, wherein a driver and a pair of switches are integrated in the IC die; and
a copper block that is disposed on the IC die,
wherein the power module comprises a power converter, and the power converter comprises the inductor, the capacitor, the driver, and the pair of switches.

15. The power module of claim 14, wherein each of the pair of switches comprises a Metal-Oxide-Semiconductor Field-Effect Transistor (MOSFET).

16. The power module of claim 14, wherein the inductor has a first end that is connected to a switch node that is formed by the pair of switches and a second end that is connected to an output voltage node of the power converter, and the capacitor has a first end that is connected to the output voltage node and a second end that is connected to a power ground.

17. The power module of claim 14, wherein the capacitor is disposed in a cavity within the layer of the substrate.

18. The power module of claim 14, wherein the substrate is a printed circuit board (PCB).

19. The power module of claim 18, wherein the PCB comprises a plurality of layers, the power stage layer is disposed on a first layer of the plurality of layers, the layer of the substrate where the inductor and the capacitor are embedded within is a second layer of the plurality of layers, and the first layer is disposed between the power stage layer and the second layer.

20. The power module of claim 19, wherein the first layer is an interposer layer.
